(19) United States
(12) Patent Application Publication
(10) Pub. No.: US 2020/0012557 A1
(43) Pub. Date: Jan. 9, 2020

(54) SOLID STATE STORAGE DEVICE AND DATA PROCESSING METHOD WHEN A POWER FAILURE OCCURS

(71) Applicants: Lite-On Electronics (Guangzhou) Limited, Guangzhou (CN); LITE-ON TECHNOLOGY CORPORATION, Taipei (TW)

(72) Inventors: Yei-Chung Lee, Taipei (TW); Shang-Chun HSIEH, Taipei (TW); Shi-Hao Tseng, Taipei (TW); Chao-Yeuan Mao, Taipei (TW)

(21) Appl. No.: 16/118,549

(22) Filed: Aug. 31, 2018

(30) Foreign Application Priority Data
Jul. 6, 2018 (CN) 201810735749.9

(51) Int. Cl. G06F 11/10; G11C 5/14; G06F 11/14

(52) U.S. Cl. CPC G06F 11/108; G11C 16/10; G06F 11/1441; G11C 5/144

(57) ABSTRACT

A solid state storage device includes a buffer, a non-volatile memory and a control circuit. A write data is temporarily stored in the buffer. The non-volatile memory includes plural dies. The plural dies include respective first spaces as data storage areas. If an amount of the write data in the buffer does not reach a predetermined data amount when a power failure occurs, the control circuit performs a parity check process on the write data to generate a parity data. The control circuit stores the write data in the data storage areas of the plural dies. The control circuit stores the parity data and a position information in a system storage area of the non-volatile memory.

This application claims the benefit of People's Republic of China Patent Application No. 201810735749.9, filed Jul. 6, 2018, the subject matter of which is incorporated herein by reference.

### FIELD OF THE INVENTION

The present invention relates to a solid state storage device and a data processing method, and more particularly to a solid state storage device and a data processing method when a power failure occurs.

### BACKGROUND OF THE INVENTION

As is well known, the early computer system uses a hard disk drive to store data. A redundant array of independent disk (RAID) is a data storage device that combines plural hard disk drives. Consequently, the performance and capacity of the RAID are superior to a single hard disk drive.

For example, the RAID comprises plural independent hard disk drives. During a write operation, a write data is divided into plural sub-write data. The plural sub-write data are written into all independent hard disk drives of the RAID.

During a read operation, a controller reads plural sub-read data from all independent hard disk drives of the RAID and combines the plural sub-read data as a read data. Consequently, the RAID has the benefits of increasing the processing performance, enhancing the data reliability and increasing the data storage capacity.

Nowadays, a solid state storage device such as a solid state drive is developed to replace the conventional hard disk drive gradually. Consequently, the concepts of the RAID are applied to the solid state storage device.

FIG. 1 is a schematic function block diagram illustrating the architecture of a conventional solid state storage device. As shown in FIG. 1, the solid state storage device 160 comprises a control circuit 162, a buffer 164 and a non-volatile memory 166. The non-volatile memory 166 comprises plural dies 111˜126. For example, the plural dies 111˜126 are NAND flash dies. The buffer 164 is a dynamic random access memory (DRAM).

The solid state storage device 160 is connected with a host 150 through an external bus 152. For example, the external bus 152 is a USB bus, an SATA bus, a PCIe bus, an M.2 bus, a U.2 bus, or the like.

Moreover, the control circuit 162 is connected with the non-volatile memory 166 and the buffer 164. According to a write command from the host 150, the control circuit 162 temporarily stores the write data from the host 150 to the buffer 164. At the appropriate time, the write data is transmitted from the buffer 164 to the non-volatile memory 166 and stored in the non-volatile memory 166. Alternatively, according to a read command from the host 150, the control circuit 162 acquires a read data from the non-volatile memory 166. In addition, the read data is transmitted to the host 150 through the control circuit 162.

For achieving the RAID performance, each of the dies 111˜126 of the non-volatile memory 166 is considered as an independent hard disk drive by the control circuit 162 of the solid state storage device 160.

For example, according to a write command from the host 150, the control circuit 162 temporarily stores the write data from the host 150 to the buffer 164. At the appropriate time, the write data in the buffer 164 is divided into plural sub-write data by the control circuit 162 and the plural sub-write data are written into the dies 111˜126. For example, when the data amount in the buffer 164 reaches a predetermined data amount, the write data in the buffer 164 is divided into plural sub-write data by the control circuit 162 and the plural sub-write data are written into the dies 111˜126.

Moreover, according to a read command from the host 150, the control circuit 162 acquires plural sub-read data from the dies 111˜126 and combines the plural sub-read data as a read data. In addition, the read data is transmitted to the host 150.

FIGS. 2A and 2B schematically illustrate the structure of a write data in the non-volatile memory of the conventional solid state storage device. As mentioned above, when the amount of the data temporarily stored in the buffer 164 reaches the predetermined data amount, the control circuit 162 starts to store the write data from the buffer 164 to the non-volatile memory 166.

Moreover, a greater portion of the space of each die is a data storage area. That is, the dies 111˜126 comprise data storage areas 111d˜126d, respectively. The write data from the host 150 can be stored in the data storage areas 111d˜126d of the corresponding dies 111˜126 by the control circuit 162. In other words, the data storage areas 111d˜126d of the corresponding dies 111˜126 are storage areas that allow the host 150 to store and read data.

Moreover, the data storage areas 111d˜126d of the dies 111˜126 are divided into plural stripes. For example, the non-volatile memory 166 comprises 16 dies 111˜126, and the stripe size set in the solid state storage device 160 is 160 Kbytes. Consequently, the control circuit 162 can write plural sub-write data to the dies 111˜126, wherein the size of each sub-write data is 10 Kbytes. For maintaining the data reliability of the non-volatile memory 166, the last die 126 is used for storing a parity data.

In other words, the specified storage spaces (e.g., 10 Kbytes) of the data storage areas 111d˜126d of the dies 111˜126 are logically combined as the storage space of one stripe. The storage space of one stripe is the stripe size.

After the amount of the write data temporarily stored in the buffer 164 reaches 150 Kbytes, the control circuit 162 performs a parity check on the 150 Kbyte write data. In other words, the amount of the write data and the parity data is equal to the stripe size (i.e., 160 Kbytes).

Moreover, the 150 Kbyte write data is divided into 15 sub-write data Da1˜Da15 by the control circuit 162. Then, the sub-write data Da1˜Da15 and the parity data Dap are stored in a first stripe SP1 corresponding to the data storage areas 111d˜126d of the dies 111˜126.

Please refer to FIG. 2A. The 10 Kbyte sub-write data Da1 is stored in the data storage area 111d of the die 111. The 10 Kbyte sub-write data Da2 is stored in the data storage area 112d of the die 112. The 10 Kbyte sub-write data Da3 is stored in the data storage area 113d of the die 113. The rest may be deduced by analogy. The 10 Kbyte sub-write data Da15 is stored in the data storage area 125d of the die 125. The 10 Kbyte parity data Dap is stored in the data storage area 126d of the die 126.

Moreover, according to a read command from the host 150, the control circuit 162 acquires 15 sub-read data Da1˜Da15 and the parity data Dap from the dies 111˜126 and combines the 15 sub-read data Da1˜Da15 and the parity data Dap as a 150 Kbyte read data. In addition, the read data is transmitted to the host 150.

Please refer to FIG. 2B. After the amount of the write data temporarily stored in the buffer 164 reaches 150 Kbytes again, the control circuit 162 performs the same action. Consequently, the sub-write data Db1˜Db15 and a parity data Dbp are stored in a second stripe SP2 corresponding to the data storage areas 111d˜126d of the dies 111˜126.

It is noted that the stripe size of the solid state storage device 160 is not restricted to 160 Kbytes and the number of the dies in the non-volatile memory 166 is not restricted to 16. For example, the non-volatile memory 166 contains n dies, and the stripe size of the solid state storage device 160 is m Kbytes. In other words, the size of each sub-write data is (m/n) Kbytes.

### SUMMARY OF THE INVENTION

An embodiment of the present invention provides a solid state storage device. The solid state storage device includes a buffer, a non-volatile memory and a control circuit. A write data is temporarily stored in the buffer. The non-volatile memory includes plural dies. The plural dies include respective first spaces as data storage areas. The control circuit is connected with a host, the buffer and the non-volatile memory. If an amount of the write data in the buffer does not reach a predetermined data amount when a power failure occurs, the control circuit performs a parity check process on the write data to generate a parity data. The control circuit stores the write data in the data storage areas of the plural dies. The control circuit stores the parity data and a position information corresponding to the parity data in a system storage area of the non-volatile memory.

Another embodiment of the present invention provides a data processing method for a solid state storage device. The solid state storage device includes a non-volatile memory with plural dies. The plural dies include respective first spaces as data storage areas. The data processing method includes the following steps. When the solid state storage device is in a normal working state, a write data is stored in a buffer and the solid state storage device continuously judges whether a power failure occurs. If an amount of the write data in the buffer does not reach a predetermined data amount when the power failure occurs, a parity check process is performed on the write data to generate a parity data. Then, the write data is stored in the data storage areas of the plural dies. Afterwards, the parity data and a position information corresponding to the parity data are stored in a system storage area of the non-volatile memory.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic function block diagram illustrating the architecture of a conventional solid state storage device;

FIGS. 2A (prior art) and 2B (prior art) schematically illustrate the structure of a write data in the non-volatile memory of the conventional solid state storage device;

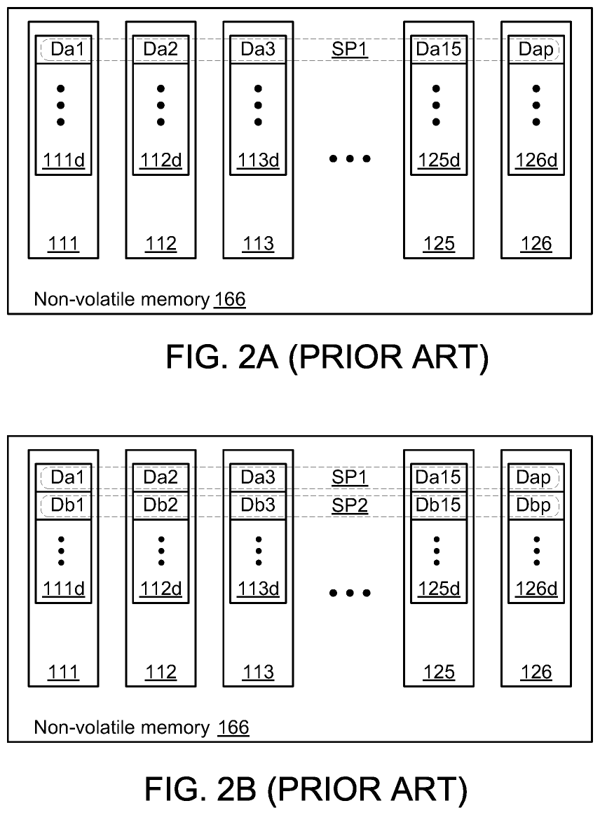

FIG. 3 is a schematic function block diagram illustrating the architecture of a solid state storage device according to an embodiment of the present invention;

FIG. 4A is a flowchart illustrating a data processing method for a solid state storage device when a power failure occurs according to a first embodiment of the present invention;

FIGS. 4B and 4C schematically illustrate the structure of a write data to be processed by the data processing method according to the first embodiment of the present invention;

FIG. 5A is a flowchart illustrating a data processing method for a solid state storage device when a power failure occurs according to a second embodiment of the present invention;

FIGS. 5B and 5C schematically illustrate the structure of a write data to be processed by the data processing method according to the second embodiment of the present invention;

FIG. 6A is a flowchart illustrating a data processing method for a solid state storage device when a power failure occurs according to a third embodiment of the present invention;

FIGS. 6B and 6C schematically illustrate the structure of a write data to be processed by the data processing method according to the third embodiment of the present invention;

FIG. 7A is a flowchart illustrating a data processing method for a solid state storage device when a power failure occurs according to a fourth embodiment of the present invention; and

FIGS. 7B and 7C schematically illustrate the structure of a write data to be processed by the data processing method according to the fourth embodiment of the present invention.

### DETAILED DESCRIPTION OF PREFERRED EMBODIMENTS

Generally, the solid state storage device for a data center should have high data reliability. Consequently, some data protecting measures should be taken to protect the solid state storage device. For example, when a power failure occurs, a suitable data protecting measure is taken.

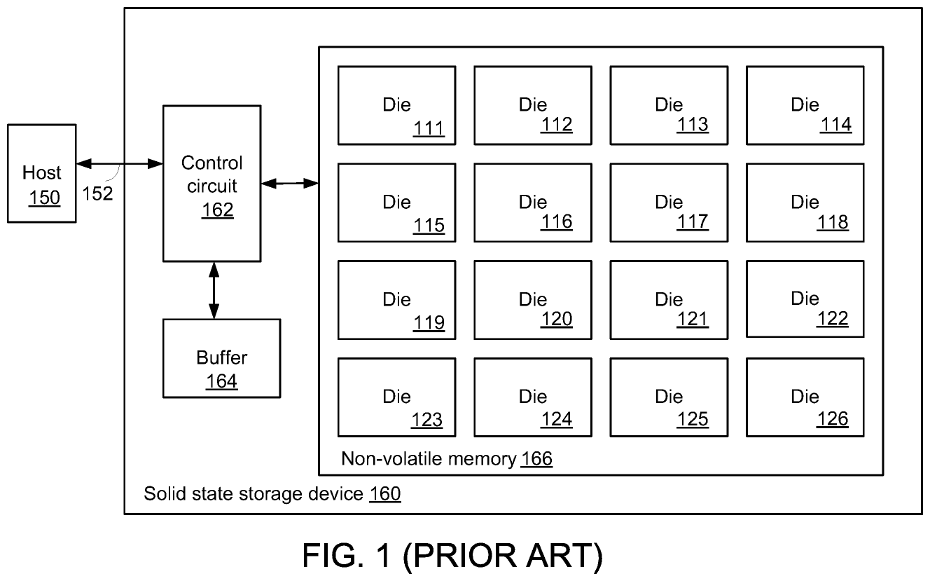

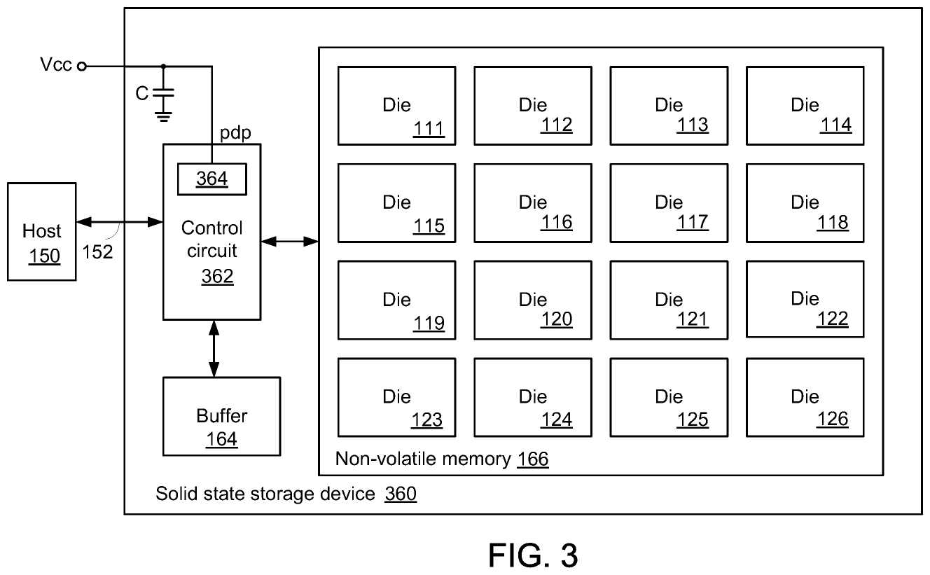

FIG. 3 is a schematic function block diagram illustrating the architecture of a solid state storage device according to an embodiment of the present invention. In comparison with the solid state storage device of FIG. 1, the control circuit 362 of the solid state storage device 360 of this embodiment comprises a voltage detector 364. The voltage detector 364 is connected with a power detecting pin pdp to detect whether the supply voltage Vcc of the solid state storage device 360 is stable.

As shown in FIG. 3, the solid state storage device 360 comprises a capacitor C. A first terminal of the capacitor C receives the supply voltage Vcc. A second terminal of the capacitor C is connected to a ground terminal. The power detecting pin pdp of the control circuit 362 is connected with the first terminal of the capacitor C.

When the solid state storage device 360 is in a normal working state, the voltage detector 364 of the control circuit 362 continuously detects the voltage of the capacitor C. If the voltage of the capacitor C drops to a specified voltage value (e.g., 0.95×Vcc), the voltage detector 364 judges that the power failure occurs. Meanwhile, the control circuit 362 has to use the residual charges of the capacitor C to perform a data protecting operation.

During the data protecting operation, the write data stored in the buffer 164 has to be stored in the non-volatile memory 166 by the control circuit 362. Consequently, even if the solid state storage device 360 is powered off, the write data in the buffer 164 will not be lost. A data processing method of the solid state storage device when a power failure occurs will be described as follows.

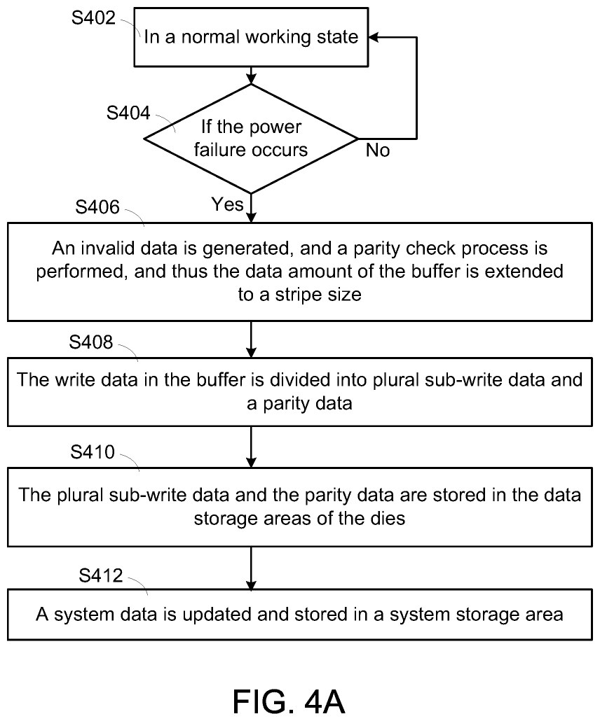

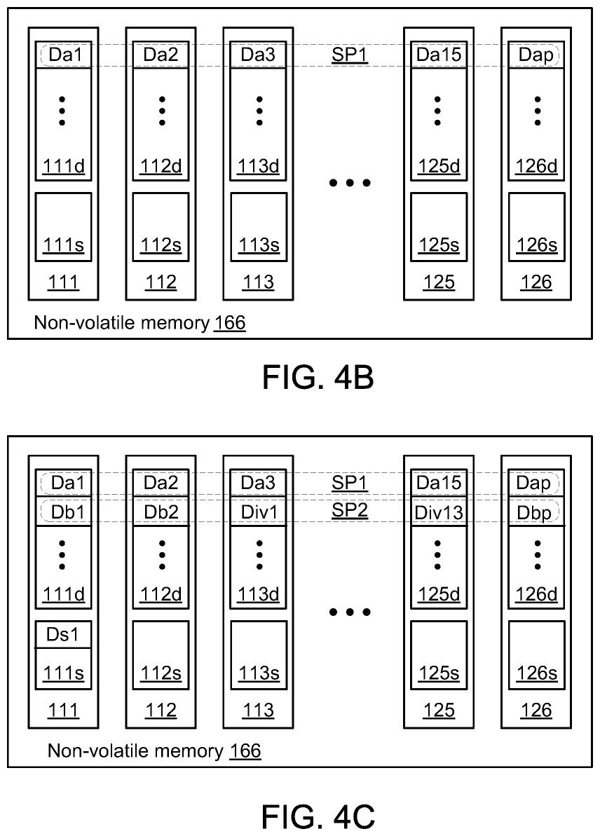

FIG. 4A is a flowchart illustrating a data processing method for a solid state storage device when a power failure occurs according to a first embodiment of the present invention.

Firstly, the solid state storage device 360 is in a normal working state (Step S402). That is, the solid state storage device 360 is in the normal working state when the power failure does not occur. Under this circumstance, the control circuit 362 can receive and execute the command from the host 150. For example, according to a write command, the control circuit 362 temporarily stores the write data in the buffer 164.

If the power failure occurs (Step S404), the control circuit 362 performs a data protecting operation. In this embodiment, the control circuit 362 generates an invalid data and performs a parity check process, and thus the data amount in the buffer 164 is extended to the stripe size (Step S406).

Then, the write data in the buffer 164 is divided into plural sub-write data and a parity data by the control circuit 362 (Step S408). Then, the plural sub-write data and the parity data are stored in the data storage areas 111d˜126d of the dies 111˜126 (Step S410).

Then, the control circuit 362 updates a system data and stores the updated system data in a system storage area (Step S412).

FIGS. 4B and 4C schematically illustrate the structure of a write data to be processed by the data processing method according to the first embodiment of the present invention.

For example, the non-volatile memory 166 comprises 16 dies 111˜126, and the stripe size set in the solid state storage device 360 is 160 Kbytes.

Moreover, a greater portion of the space of each die is a data storage area. That is, the dies 111˜126 comprise data storage areas 111d˜126d, respectively. The spaces 111s˜126s of the dies 111˜126 are collaboratively defined as a system storage area. The data storage areas 111d˜126d of the corresponding dies 111˜126 are storage areas that allow the host 150 to store and read data. Whereas, the data in the system storage area is not accessible by the host 150.

Generally, the system storage area stores a system data. The system data contains the information about the solid state storage device 360. For example, the system data contains the information about the available space range of the data storage areas 111d˜126d of the corresponding dies 111˜126, the position of the bad block or the recorded occurrence event.

Before the solid state storage device 360 is powered off, the control circuit 362 updates a system data and stores the updated system data in the system storage area. When the solid state storage device 360 is powered on again, the control circuit 362 initializes the solid state storage device 360 according to the latest system data in the system storage area. Consequently, the solid state storage device 360 can be normally operated.

As shown in FIG. 4B, the sub-write data Da1˜Da15 and the parity data Dap have been stored in a first stripe SP1 corresponding to the data storage areas 111d˜126d of the dies 111˜126 before the power failure occurs.

It is assumed that only 20 Kbyte write data is stored in the buffer 164 when the power failure occurs. Consequently, the control circuit 362 generates 130 Kbyte invalid data. In addition, the control circuit 362 performs a parity check process to generate 10 Kbyte parity data. That is, the data amount in the buffer 164 is extended to the stripe size (i.e., 160 Kbytes).

As shown in FIG. 4C, the write data in the buffer 164 is divided into 15 sub-write data Db1, Db2, Div1˜Div13 and the parity data Dbp by the control circuit 362. The sub-write data Div1˜Div13 are invalid data. Then, the sub-write data Db1, Db2, Div1˜Div13 and the parity data Dbp are stored in a second stripe SP2 corresponding to the data storage areas 111d˜126d of the dies 111˜126.

Then, the control circuit 362 updates a system data Ds1 and stores the updated system data Ds1 in the system storage area 111s.

After the above process, the residual charges in the capacitor C are gradually exhausted. Then, the solid state storage device 360 is powered off.

From the above descriptions, the present invention provides the data processing method for the solid state storage device. When a power failure occurs, the control circuit 362 uses the residual charges of the capacitor C to perform the data protecting operation so as to prevent from data loss and enhance the data accuracy.

However, during the process of performing the data protecting operation, the control circuit 362 needs to generate the invalid data, perform the parity check process, store the sub-write data and the parity data in the data storage areas 111d˜126d of the dies 111˜126, and update the system data in the system storage area. In other words, the residual charges of the capacitor are possibly insufficient to complete all of the above actions. Consequently, the data processing method of the first embodiment needs to be further modified.

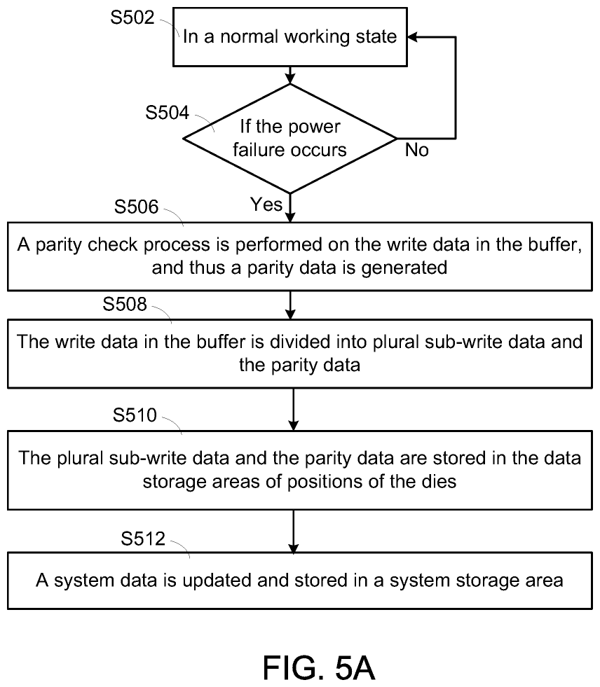

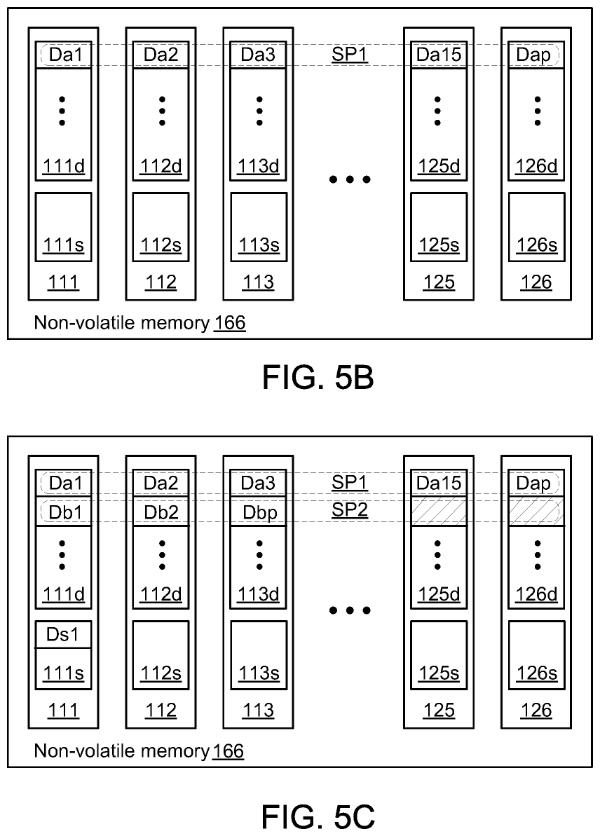

FIG. 5A is a flowchart illustrating a data processing method for a solid state storage device when a power failure occurs according to a second embodiment of the present invention.

Firstly, the solid state storage device 360 is in a normal working state (Step S502). That is, the solid state storage device 360 is in the normal working state when the power failure does not occur. Under this circumstance, the control circuit 362 can receive and execute the command from the host 150. For example, the command is a write command or a read command.

If the power failure occurs (Step S504), the control circuit 362 performs a data protecting operation. In this embodiment, the control circuit 362 performs a parity check process to generate a parity data according to the write data in the buffer 164 (Step S506).

Then, the write data in the buffer 164 is divided into plural sub-write data and a parity data by the control circuit 362 (Step S508). Then, the plural sub-write data and the parity data are stored in the data storage areas of portions of the dies (Step S510).

Then, the control circuit 362 updates a system data and stores the updated system data in a system storage area (Step S512).

FIGS. 5B and 5C schematically illustrate the structure of a write data to be processed by the data processing method according to the second embodiment of the present invention. For example, the non-volatile memory 166 comprises 16 dies 111˜126, and the stripe size set in the solid state storage device 360 is 160 Kbytes.

As shown in FIG. 5B, the sub-write data Da1˜Da15 and the parity data Dap have been stored in a first stripe SP1 corresponding to the data storage areas 111d˜126d of the dies 111˜126 before the power failure occurs.

It is assumed that only 20 Kbyte write data is stored in the buffer 164 when the power failure occurs. The control circuit 362 performs a parity check process to generate 10 Kbyte parity data according to the write data in the buffer 164. The data amount in the buffer 164 is extended to 30 Kbytes. That is, the data amount in the buffer 164 is not extended to the stripe size. In the second embodiment, the control circuit 362 does not generate invalid data to extend the data amount to the stripe size.

As shown in FIG. 5C, the write data in the buffer 164 is divided into two sub-write data Db1, Db2 and the parity data Dbp by the control circuit 362. Then, the sub-write data Db1, Db2 and the parity data Dbp are stored in a second stripe SP2 corresponding to the data storage areas 111d˜113d of the dies 111˜113. The other portions of the second stripe SP2 corresponding to the data storage areas 114d˜126d of the dies 114˜126 (e.g., the regions marked by oblique lines) store no data. Consequently, the write data in the buffer will not be lost after power off.

Then, the control circuit 362 updates a system data Ds1 and stores the updated system data Ds1 in the system storage area 111s.

After the above process, the residual charges in the capacitor C are gradually exhausted. Then, the solid state storage device 360 is powered off.

In comparison with the first embodiment, it is not necessary to generate the invalid data in the data processing method of the second embodiment. Consequently, the control circuit 362 is able to complete the above action in time. In the second embodiment, after the parity data Dbp is stored in the data storage area 113d of the die 113, the other space of the corresponding strip (e.g., the portions of the second stripe SP2 corresponding to the data storage areas 114d˜126d of the dies 114˜126 and marked by oblique lines) cannot be used to store other sub-write data. After the solid state storage device 360 is powered on again, the new write data will be stored in another stripe (e.g., the third stripe SP3). As mentioned above, in the second embodiment, the storing space of the portion of the second stripe SP2 that is marked by oblique lines is wasted.

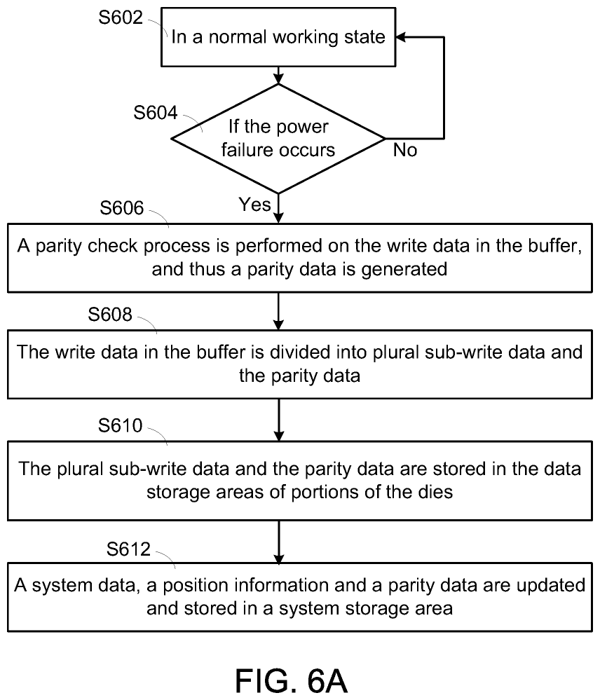

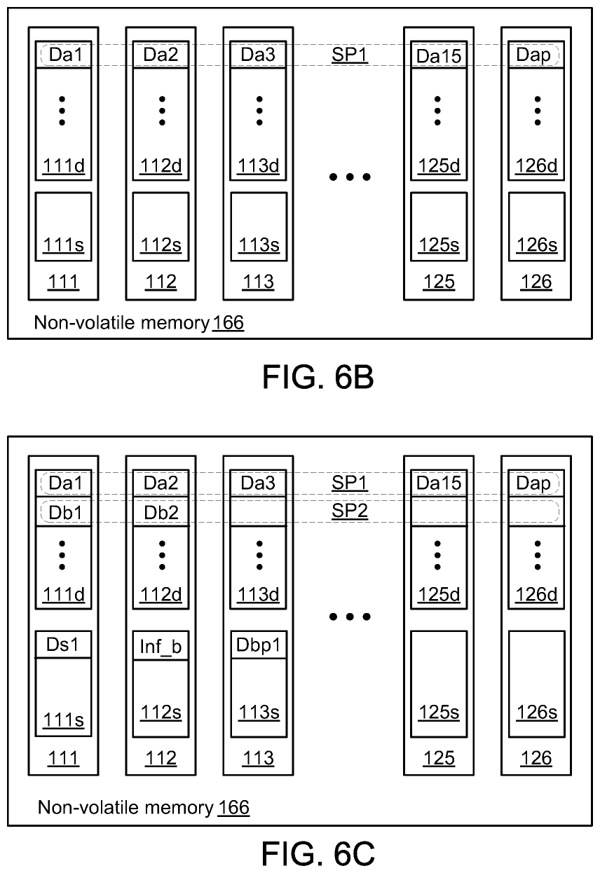

FIG. 6A is a flowchart illustrating a data processing method for a solid state storage device when a power failure occurs according to a third embodiment of the present invention.

Firstly, the solid state storage device 360 is in a normal working state (Step S602). That is, the solid state storage device 360 is in the normal working state when the power failure does not occur. Under this circumstance, the control circuit 362 can receive and execute the command from the host 150. For example, according to a write command, the control circuit 362 temporarily stores the write data in the buffer 164.

If the power failure occurs (Step S604), the control circuit 362 performs a data protecting operation. In this embodiment, the control circuit 362 performs a parity check process to generate a parity data according to the write data in the buffer 164 (Step S606).

Then, the write data in the buffer 164 is divided into plural sub-write data and the parity data by the control circuit 362 (Step S608). Then, the plural sub-write data are stored in the data storage areas of portions of the dies (Step S610).

Then, the control circuit 362 updates and stores a system data, a position information and a parity data in a system storage area (Step S612).

FIGS. 6B and 6C schematically illustrate the structure of a write data to be processed by the data processing method according to the third embodiment of the present invention. For example, the non-volatile memory 166 comprises 16 dies 111˜126, and the stripe size set in the solid state storage device 360 is 160 Kbytes.

As shown in FIG. 6B, the sub-write data Da1˜Da15 and the parity data Dap have been stored in a first stripe SP1 corresponding to the data storage areas 111d˜126d of the dies 111˜126 before the power failure occurs.

It is assumed that only 20 Kbyte write data is stored in the buffer 164 when the power failure occurs. The control circuit 362 performs a parity check process to generate 10 Kbyte parity data according to the write data in the buffer 164. The data amount in the buffer 164 is extended to 30 Kbytes. That is, the data amount in the buffer 164 is not extended to the stripe size. In the third embodiment, the control circuit 362 does not generate invalid data to extend the data amount to the stripe size.

As shown in FIG. 6C, the write data in the buffer 164 is divided into two sub-write data Db1, Db2 and the parity data Dbp1 by the control circuit 362. Then, the sub-write data Db1, Db2 are stored in a second stripe SP2 corresponding to the data storage areas 111d˜112d of the dies 111˜112. The other portions of the second stripe SP2 corresponding to the data storage areas 113d˜126d of the dies 113˜126 store no data.

Then, the control circuit 362 stores a system data Ds1, a position information Inf_b and a parity data Dbp1 in the system storage areas 111s˜113s. The position information Inf_b indicates the storage positions of the sub-write data Db1 and Db2 in the non-volatile memory 166. Besides, the parity data Dbp1 is obtained by performing the parity check process on the sub-write data Db1 and Db2 corresponding to the position information Inf_b. In other words, according to the position information Inf_b, the control circuit 362 can recognize that the parity data Dbp1 is corresponding to which sub-write data in the non-volatile memory 166.

After the above process, the residual charges in the capacitor C are gradually exhausted. Then, the solid state storage device 360 is powered off.

That is, when the power failure occurs, it is not necessary to generate the invalid data. Consequently, the control circuit 362 is able to complete the above action in time. Since the parity data Dbp1 is stored in the system storage areas 111s˜113s, the other space of the corresponding stripe can be continuously used to store the sub-write data. After the solid state storage device 360 is powered on again, the new write data will be stored in the stripe with the latest sub-write data. Take FIG. 6C as an example, after the solid state storage device 360 is powered on again, the new data is stored in the second stripe SP2 corresponding to the data storage areas 113d˜126d of the dies 113˜126.

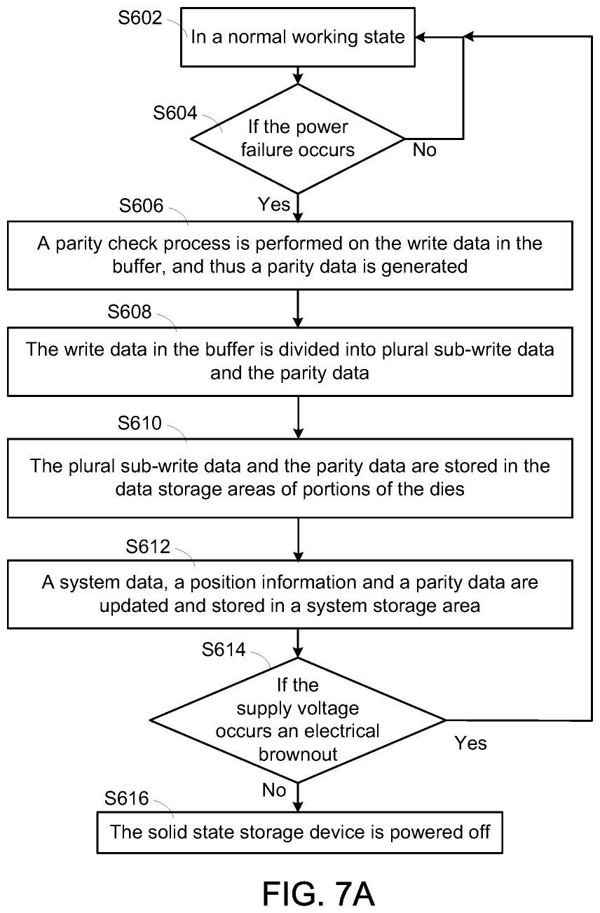

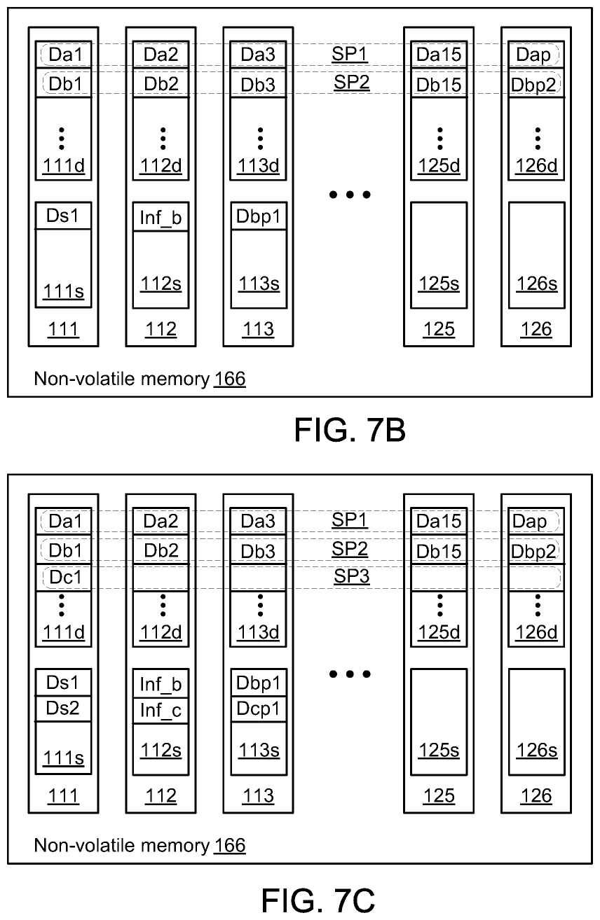

FIG. 7A is a flowchart illustrating a data processing method for a solid state storage device when a power failure occurs according to a fourth embodiment of the present invention. In comparison with the third embodiment, the data processing method of the fourth embodiment further comprises a step of judging whether the supply voltage Vcc occurs an electrical brownout (Step S614).

Generally, after the power failure occurs, the control circuit 362 performs the data protecting operation. As the residual charges in the capacitor C are gradually exhausted, the solid state storage device 360 is powered off (Step S616). However, if the supply voltage Vcc is restored to the normal level before the residual charges in the capacitor C are completely exhausted, it means that the supply voltage Vcc occurs an electrical brownout.

If the judging result of the step S614 indicates that the supply voltage Vcc occurs the electrical brownout, the control circuit 362 performs the step S602 again. Consequently, the solid state storage device 360 backs to the normal working state again.

FIGS. 7B and 7C schematically illustrate the structure of a write data to be processed by the data processing method according to the fourth embodiment of the present invention. After the operation of FIG. 6C, the structure of the write data stored in the non-volatile memory is shown in FIG. 7B.

As shown in FIG. 6C, the system data Ds1, the position information Inf_b and the parity data Dbp1 are stored in the system storage areas 111s˜113s by the control circuit 362. Then, the control circuit 362 performs the step of judging whether the supply voltage Vcc occurs the electrical brownout (Step S614). If the judging result of the step S614 indicates that the supply voltage Vcc does not occur the electrical brownout, the supply voltage Vcc is not restored to the normal level and the residual charges in the capacitor C are gradually exhausted. Consequently, the solid state storage device 360 is powered off (Step S616). If the judging result of the step S614 indicates that the supply voltage Vcc occurs the electrical brownout, the supply voltage Vcc is restored to the normal level. Consequently, the solid state storage device 360 is in the normal working state again.

When back to the normal working state, as mentioned above, the 20 Kbyte write data has been temporarily stored in the buffer 164. After the control circuit 362 receives the 130 Kbyte write data again, the control circuit 362 performs a parity check process on the write data of the buffer 164 to generate 10 Kbyte parity data Dbp2. That is, the data amount in the buffer 164 is extended to the stripe size.

Please refer to FIG. 7B. In the normal working state, the write data that has not been written into the non-volatile memory 166 is divided into 13 sub-write data Db3-Db15 by the control circuit 362. Then, the sub-write data Db3-Db15 and the parity data Dbp2 are stored in a second stripe SP2 corresponding to the data storage areas 113d˜126d of the dies 113˜126.

Then, please refer to FIG. 7C. It is assumed that 10 Kbyte write data is stored in the buffer 164 when the power failure occurs. The control circuit 362 performs a parity check process to generate 10 Kbyte parity data according to the write data in the buffer 164. The data amount in the buffer 164 is extended to 20 Kbytes only. That is, the data amount in the buffer 164 is not extended to the stripe size.

Then, the write data in the buffer 164 is divided into one sub-write data Dc1 and the parity data Dcp1 by the control circuit 362. Then, the sub-write data Dc1 is stored in a third stripe SP3 corresponding to the data storage area 111d of the die 111. The other portion of the third stripe SP3 corresponding to the data storage areas 112d˜126d store no data.

Then, the control circuit 362 stores a system data Ds2, a position information Inf_c and a parity data Dcp1 in the system storage areas 111s˜113s. That is, the system data Ds1, the position information Inf_b and the parity data Dbp1 are updated by the system data Ds2, the position information Inf_c and the parity data Dcp1, respectively.

After the above actions are completed, the control circuit 362 judges whether the voltage Vcc occurs the electrical brownout. If the supply voltage Vcc does not occur the electrical brownout, the supply voltage Vcc is not restored to the normal level and the residual charges in the capacitor C are gradually exhausted. Consequently, the solid state storage device 360 is powered off.

From the above descriptions, the present invention provides a solid state storage device and a data processing method when a power failure occurs. The control circuit 362 of the solid state storage device 360 comprises the voltage detector 364 for judging whether the power failure occurs. When a power failure occurs, the write data in the buffer 164 is stored in the non-volatile memory 166 by the control circuit 362. Consequently, the write data is not lost. And, the parity data corresponding to the write data is stored in the data storage area or the system storage area. Consequently, the accuracy of the write data is enhanced.

In some other embodiments, the voltage detector 364 is disposed outside of the control circuit 362. When the voltage detector 364 judges that the power failure occurs, the voltage detector 364 notifies the control circuit 362 to perform the data protecting operation.

Moreover, the spaces 111s˜126s of the dies 111˜126 are collaboratively defined as the system storage area. It is noted that numerous modifications and alterations may be made while retaining the teachings of the invention. For example, in another embodiment, the non-volatile memory further comprises an additional die. The space of the additional die can be used as the system storage area.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A solid state storage device, comprising:
a buffer, wherein a write data is temporarily stored in the buffer;
a non-volatile memory comprising plural dies, wherein the plural dies comprise respective first spaces as data storage areas, and the data storage areas is divided into plural stripes; and
a control circuit connected with a host, the buffer and the non-volatile memory,
wherein if an amount of the write data in the buffer does not reach a predetermined data amount when a power failure occurs, the control circuit performs a parity check process on the write data to generate a parity data, wherein the control circuit stores the write data in the data storage areas of the plural dies and stores the parity data and a position information corresponding to the parity data in a system storage area of the non-volatile memory.

2. The solid state storage device as claimed in claim 1, wherein the position information indicates storage positions of the write data stored in the non-volatile memory.

3. The solid state storage device as claimed in claim 1, wherein the solid state storage device further comprises a voltage detector for detecting if the power failure occurs or if a supply voltage of the solid state storage device occurs an electrical brownout.

4. The solid state storage device as claimed in claim 3, wherein if the supply voltage of the solid state storage device drops to a specified voltage value, the voltage detector judges that the power failure occurs.

5. The solid state storage device as claimed in claim 1, wherein if a total amount of the write data and the parity data is lower than a stripe size, the control circuit judges that the amount of the write data does not reach the predetermined data amount.

6. The solid state storage device as claimed in claim 1, wherein the write data is stored in a first stripe corresponding to the data storage areas of the plural dies when the power failure occurs, wherein when the solid state storage device is powered on again to store a new data, the new data is firstly stored in the first stripe.

7. The solid state storage device as claimed in claim 1, wherein when the power failure occurs, the control circuit further generates a system data and stores the system data in the system storage area.

8. The solid state storage device as claimed in claim 1, wherein the plural dies further comprise respective second spaces, wherein the system storage area is defined by the second spaces of the plural dies collaboratively.

9. A data processing method for a solid state storage device, the solid state storage device comprising a non-volatile memory with plural dies, the plural dies comprising respective first spaces as data storage areas, the data storage areas is divided into plural stripes, the data processing method comprising steps of:
when the solid state storage device is in a normal working state, storing a write data in a buffer and continuously judging whether a power failure occurs; and
if an amount of the write data in the buffer does not reach a predetermined data amount when the power failure occurs, performing a parity check process on the write data to generate a parity data; storing the write data in the data storage areas of the plural dies; and storing the parity data and a position information corresponding to the parity data in a system storage area of the non-volatile memory.

10. The data processing method as claimed in claim 9, wherein the position information indicates storage positions of the write data stored in the non-volatile memory.

11. The data processing method as claimed in claim 9, wherein if a supply voltage of the solid state storage device drops to a specified voltage value, it is judged that the power failure occurs.

12. The data processing method as claimed in claim 9, wherein if a total amount of the write data and the parity data is lower than a stripe size, it is judged that the amount of the write data does not reach the predetermined data amount.

13. The data processing method as claimed in claim 9, wherein the write data is stored in a first stripe corresponding to the data storage areas of the plural dies when the power failure occurs, wherein when the solid state storage device is powered on again to store a new data, the new data is firstly stored in the first stripe.

14. The data processing method as claimed in claim 9, wherein when the power failure occurs, the data processing method further comprises a step of generating a system data and storing the system data in the system storage area.

15. The data processing method as claimed in claim 9, wherein the plural dies further comprise respective second spaces, wherein the system storage area is defined by the second spaces of the plural dies collaboratively.

16. The data processing method as claimed in claim 9, wherein after the power failure occurs, the data processing method further comprises a step of judging whether a supply voltage of the solid state storage device occurs an electrical brownout, wherein if the supply voltage of the solid state storage device occurs the electrical brownout, the solid state storage device is restored to the normal working state.

17. The data processing method as claimed in claim 16, wherein if the supply voltage of the solid state storage device is restored to a normal level after the power failure occurs, it is judged that the supply voltage of the solid state storage device occurs the electrical brownout.
